(19) United States
(12) Patent Application Publication
(10) Pub. No.: US 2025/0015220 A1
(43) Pub. Date: Jan. 9, 2025

(54) PASSIVATING AND CONDUCTING LAYERED STRUCTURE FOR SOLAR CELLS

(71) Applicant: Forschungszentrum Juelich GmbH, Juelich (DE)

(72) Inventors: Kaining DING, Wuerselen (DE); Manuel POMASKA, Cologne (DE); Kaifu QIU, Yiwu (CN)

(21) Appl. No.: 18/262,921

(22) PCT Filed: Dec. 15, 2021
(86) PCT No.: PCT/DE2021/000205

§ 371 Date: Jul. 26, 2023

(30) Foreign Application Priority Data
Feb. 2, 2021 (DE) 10 2021 000 501.5

(51) Int. Cl. H01L 31/0745; H01L 31/0216; H01L 31/0236; H01L 31/18

(52) U.S. Cl. CPC H01L 31/0745; H01L 31/02167; H01L 31/02168; H01L 31/02363; H01L 31/1868

(57) ABSTRACT

A layered structure is provided for a solar cell having tunnel-oxide-passivated contacts. The layered structure includes at least one tunnel oxide layer and a μc-SiCx layer, wherein x≥0.5. A solar cell having tunnel-oxide-passivated contacts is also provided. The solar cell includes at least one crystalline n-doped or p-doped silicon layer, and the layered structure having the tunnel-oxide passivated contacts. A method for producing a layered structure for a solar cell having tunnel-oxide-passivated contacts is additionally provided. The method includes providing a substrate layer comprising a silicon layer, depositing a tunnel oxide layer on the substrate layer, and depositing a u c-SiCx:H layer, which is n-doped or p-doped, on the tunnel oxide layer.

### CROSS REFERENCE TO RELATED APPLICATIONS

This application is a U.S. National Phase application under 35 U.S.C. § 371 of International Application No. PCT/DE2021/000205, filed on Dec. 15, 2021, and claims benefit to German Patent Application No. DE 10 2021 000 501.5, filed on Feb. 2, 2021. The International Application was published in German on Aug. 11, 2022 as WO 2022/167018 A1 under PCT Article 21 (2).

### FIELD

The present disclosure relates to a transparent, tunnel-oxide-passivated layered structure for solar cells, in particular high-temperature stable solar cells. The present disclosure further relates to solar cells containing a transparent, passivating and conducting layered structure, arranged, for example, on the front side of such solar cells, and further relates to a method for producing such a layered structure and such solar cells.

### BACKGROUND

In order to come as close as possible to the theoretically maximum achievable efficiency of solar cells, various methods and processes are currently being developed to increase the efficiency of solar cells and reduce internal losses. At the same time, the solar cells are to be produced cost-effectively.

The efficiency of solar cells can be increased by reducing loss mechanisms. The parameters of charge carrier recombination and light efficiency are particularly important.

Therefore, one goal of research and development is to avoid the recombination of charge carriers, to transfer free charge carriers with as little loss as possible and to couple the light optimally.

One possible method for optimizing charge carrier transport is tunnel-oxide-passivated contact (TOPCon) technology. With such technology, the back-side contact consists of an ultra-thin tunnel oxide layer and a thin silicon layer. For contacting, an ultra-thin tunnel oxide back-side contact is deposited on the back side of the silicon cell, in most cases over the entire surface. Such silicon oxide passivating layer is only one to two nanometers thick. The charge carriers may overcome such barrier layer by means of quantum mechanical tunneling processes. A thin layer of highly doped silicon is deposited over the entire surface of such tunnel oxide layer [7].

Up to now, TOPCon technology has usually only been used for back-side contacts. This is because n-type polycrystalline Si(poly-Si(n)) adversely exhibits parasitic optical absorption, due to its optical material properties. To reduce such parasitic absorption of the poly-Si layer, some solutions have already been developed.

One of the current approaches to reduce the parasitic absorption in poly-Si is to develop an extremely thin poly-Si layer with sufficiently good passivating effects and at the same time small layer resistance. At the same time, the paste of the material for electrical contacting and the firing profile must be adapted to the extremely thin poly-Si(n) within the framework of the production method. Another approach is to replace the poly-Si(n) with alternative materials such as nc-SiOx, which has a large band gap. In addition, work is underway to use the poly-Si(n) only locally under the metal contacts in order to reduce or bypass parasitic absorption.

The solution of developing an extremely thin poly-Si layer results in good passivation (iVoc>740 mV) prior to metal coating, but after coating there is a high probability that, for example, the silver paste for electrical contacting will fire through the extremely thin poly-Si(n) and contact the c-Si directly, again degrading the passivation. Research into new pastes for the extremely thin poly-Si(n) is ongoing, but no progress is currently being made. Additionally, the firing profile is critical and difficult to control.

The second solution using nc-SiOx as an electron-selective material also shows good passivation (iVoc>725 mV), but the layer thickness of such tunnel oxide can increase during nc-SiOx deposition and exceed 2 nm, which deteriorates the charge carrier transport.

In order to use the poly-Si(n) locally under the metal contacts, the poly-Si(n) has to be deposited locally in a structured manner, which has to be realized with a costly structuring process. Therefore, a cost-effective structuring process would have to be developed to reduce the complexity of manufacturing and thus the production costs, so that the manufactured solar cell could gain industrial acceptance.

Currently, there are no known solutions to establish the advantageous TOPCon technology on the front side of solar cells as well, and thus to benefit from the excellent passivation properties of TOPCon technology.

### SUMMARY

In an embodiment, the present disclosure provides a layered structure for a solar cell having tunnel-oxide-passivated contacts. The layered structure includes at least one tunnel oxide layer and a μc-SiCx layer, wherein x≥0.5. In another embodiment, the present disclosure provides a solar cell having tunnel-oxide-passivated contacts. The solar cell includes at least one crystalline n-doped or p-doped silicon layer, and the layered structure having the tunnel-oxide passivated contacts. In a further embodiment, the present disclosure provides a method for producing a layered structure for a solar cell having tunnel-oxide-passivated contacts. The method includes providing a substrate layer comprising a silicon layer, depositing a tunnel oxide layer on the substrate layer, and depositing a u c-SiCx:H layer, which is n-doped or p-doped, on the tunnel oxide layer.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a solar cell with a boron-diffused emitter;

FIG. 2 illustrates a solar cell with p-type poly-Si as an emitter; and

FIG. 3 illustrates a solar cell with hydrogenated p-type u c-SiCx as an emitter.

### DETAILED DESCRIPTION

The present disclosure provides the technology of tunnel-oxide-passivated contacts (TOPCon technology) not only for back-side contacting but also for the front side of solar cells, in particular for high-temperature solar cells, and thus also provides a solar cell with improved efficiency compared to the prior art. Furthermore, the present disclosure provides a method for producing such tunnel-oxide-passivated contacts, in particular for the front side of solar cells, and to provide solar cells comprising such contacts.

Within the framework of the present disclosure, it was found that, by using μc-SiCx(n):H, in particular hydrogenated μc-SiCx(n):H, the technology of tunnel-oxide-passivated contacts can be used and established on the front side of solar cells, in particular high-temperature solar cells, in addition to back-side contacting.

Compared to the use of poly-Si(n) as an electron-selective and passivating layer known in the prior art for TOPCon technology, the use of μc-SiCx(n), in particular hydrogenated μc-SiCx(n):H, has the advantage that such material does not cause any parasitic optical absorption due to its transparent properties, but still fulfills the required properties of passivation and enables the selective transport of electrons. This makes it possible to benefit from the excellent passivation of TOPCon technology for the front-side contact as well, and thus to further improve the efficiency of the solar cells.

The present disclosure provides a layered structure for solar cells, preferably for high-temperature solar cells, having tunnel-oxide-passivated contacts on the front side or on the front and back side of the solar cells, consisting of at least one tunnel oxide layer, in particular a silicon oxide layer SiOx where x=1-2 or an aluminum oxide layer AlOx where x=1-2 and a μc-SiCx(n) layer, with x≥0.5, preferably ≥0.5 to 0.9, where (n)=n-doped, and wherein in an advantageous embodiment μc-SiCx(n) is a hydrogenated μc-SiCx:H(n) layer. Such layered structure can preferably be configured as a front-side contact of a solar cell, preferably a high-temperature solar cell. Thereby, the tunnel oxide layer should preferably have a layer thickness in the range of 1-2 nm in order to exhibit sufficient chemical passivating and tunneling properties.

As previously mentioned, poly-Si(n), which is commonly used for back-side TOPCon according to the prior art, can be replaced, according to the present disclosure, with conductive microcrystalline (n-type) silicon carbide (μc-SiCx(n)) with a large band gap and is used in particular for front-side TOPCon. If the optical band gap (E04) at α=104 cm⁻¹ is used, the band gap of the hydrogenated u c-SiCx(n) can reach 2.9 eV. An optical band gap of the hydrogenated μ c-SiCx(n) layer in the range of 2.3 to 2.9 eV was found to be advantageous.

Due to the large band gap, the hydrogenated u c-SiCx(n) can now be used on the front side of a solar cell. The parasitic optical absorption of the hydrogenated u c-SiCx(n):H(n) is low compared to, for example, poly-Si(n) or nc-Si:H(n). For example, at a photon energy E of 2 eV, u c-SiCx(n):H(n) has an absorption coefficient α of 2210 cm⁻¹ in contrast to poly-Si(n) or nc-Si:H(n) with a value of 17737 cm⁻¹ and 13511 cm⁻¹, such that advantageously a high layer thickness, for example in a range of 30 to 200 nm, is possible, which thereby also advantageously protects against the paste for the electrical contact layer or the metallization of the solar cell from firing through and thus prevents direct contact of the paste with the c-Si semiconductor material of the solar cells. Furthermore, due to the material used, no oxygen precursor is present during the deposition of the u c-SiCx(n), so the thickness of the tunnel oxide also remains constant and the charge carrier transport on the tunnel oxide is ensured by tunneling.

In an advantageous embodiment of the layer arrangement, carbon is preferably added to the microcrystalline hydrogenated n-type silicon carbide material, such that a C-rich and/or doped/alloyed u c-SiCx:H(n) layer can be provided. Thereby, the ratio of Si to C can advantageously be in the range of 1.0:0.7. However, a ratio of Si to C of 1.0: ≥0.7 to 1.0 is also possible. By adding more C and/or other elements to the SiC network, the thermal stability of the hydrogenated u c-SiCx:H(n) can be improved, because hydrogen is more stably bound in such a network, increasing the thermal stability of the material. Adding carbon C to the SiC network material can increase the diffusion energy of hydrogen, resulting in a lower diffusion coefficient for hydrogen, which in turn corresponds to higher thermal stability of hydrogen in the network. The quantifiable numerical values for bound H are of the order of 1 E22 cm⁻³.

In another advantageous embodiment of the layer arrangement, a cover layer is deposited on the μ c-SiCx:H(n) layer. This can be made of a material that prevents hydrogen effusion from the solar cell and in particular from the layered structure. Thereby, the cover layer can consist of SiNx:H material, wherein x can assume values in the range of x=0.3 to 1.5.

In an advantageous embodiment, the cover layer has a concentration gradient with respect to the Si content and the N content. Thereby, for example, the cover layer can be divided into three concentration sections with respect to Si content and N content:

The lowest SiNx:H concentration section, which is in direct contact with the u c-SiCx:H(n) layer, is rich in Si, enabling hydrogenation and good passivation quality. Here, the N/Si ratio (x) is in a range <1, preferably from 0.3 to 0.9.

In contrast, the uppermost SiNx:H concentration section is rich in N. Here, the N/Si ratio (x) is in a range >1. For example, in an N-rich state, the N/Si ratio (x) is 1.1-1.5. Such layer has a higher binding energy with hydrogen than that with silicon and, according to previous findings, prevents hydrogen effusion at high firing temperatures of up to 800° C. In addition, N-rich SiNx is well suited as an anti-reflective layer.

The middle SiNx:H-concentration section is a stoichiometric silicon nitride layer, which is required for the layer stack of Si-rich SiNx:H, stoichiometric SiNx:H, and N-rich SiNx:H. A stoichiometric silicon nitride has an N/Si ratio (x) of 1.

Such three-layer stack has the ability to block hydrogen leakage from the layer arrangement described herein.

In principle, however, all materials that can effectively block the diffusion of hydrogen may also be used as cover layers. In each case, such diffusion of hydrogen from the SiC:H material can be measured.

The present disclosure further provides a solar cell having tunnel-oxide-passivated contacts, comprising at least one crystalline n-doped or p-doped silicon layer on which a layered structure according to one of the preceding claims is deposited as a front-side contact or as a front-side and back-side contact.

The present disclosure further relates to a method for producing the layered structure and to a solar cell containing such layered structure.

Thereby, the method comprises the following steps: Provision of a substrate layer comprising a silicon layer; Deposition of a tunnel oxide layer on the substrate layer; and Deposition of an n-doped or p-doped μ c-SiCx:H layer on the tunnel oxide layer.

In an advantageous embodiment of the method, a cover layer is deposited on the u c-SiCx:H layer. In an advantageous embodiment, this should be made of a material that prevents hydrogen effusion from the layers beneath it. In a particularly advantageous embodiment, the cover layer consists of an SiNxH layer and has the three-stage concentration gradient described above, in particular with regard to the Si content and the N content.

In principle, the following should be taken into account when producing the layered structure, for example by means of PECVD:

For SiC deposition, the monomethylsilane flow rate, filament temperature and substrate temperature are critical. For SiN deposition, the flow rates of silane and nitrogen, substrate temperature, power and base pressure during deposition are critical. Among them, the power during SiNx deposition must be noted, because PEC VD deposition causes plasma damage to SiC, which should be well controlled so as not to affect the passivation.

Although embodiments have been illustrated and described in detail in the drawings and the preceding description, such figures and descriptions should be regarded as illustrative or exemplary and not as limiting. It should be understood that within the scope of the appended claims, changes and modifications may be made using conventional skills. In particular, the present disclosure comprises further embodiments with any combination of features of the various embodiments described above and below.

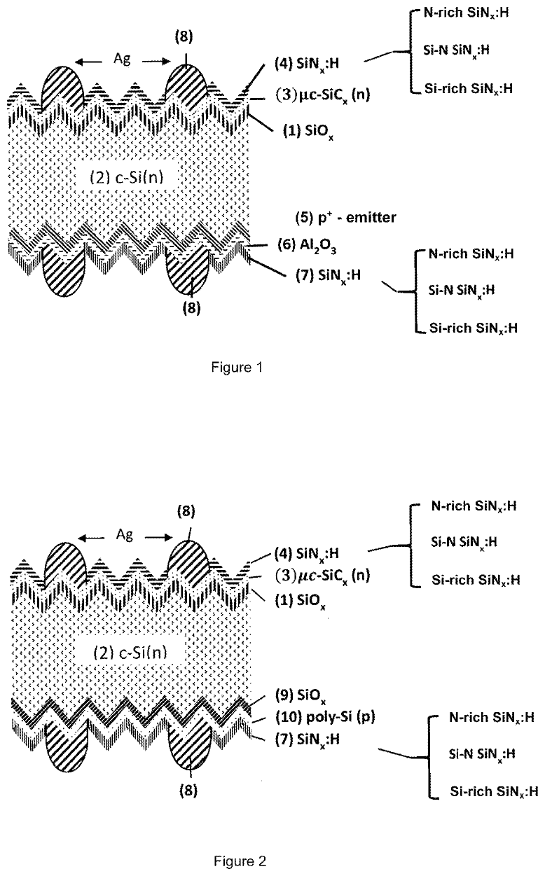

FIG. 1 shows an example of a schematic structure of a high-temperature solar cell with the layered structure on the front side of the solar cell. The layered structure has the transparent, tunnel-oxide-passivated contacts comprises a tunneling silicon oxide layer SiOx 1, which is deposited on the front side to the surface of the substrate layer 2 made of crystalline, n-doped silicon c-Si(n). A hydrogenated μ c-SiCx layer 3 is deposited on the silicon oxide SiOx layer 1. Such μ c-SiCx layer 3, which is preferably hydrogenated, acts as an electron-selective contact layer. The μ c-SiCx 3 can be deposited by means of HWCVD, for example, resulting in good crystallinity and conductivity. According to [1, 2], the conductivity of μ c-SiCx increases after a high-temperature annealing process, which has a positive effect on vertical charge carrier transport. The c-Si bulk serves as the main channel for lateral charge carrier transport due to the excellent surface passivation of the passivated contact [3]. A cover layer 4 of SiNx:H is deposited on the μ c-SiCx layer 3, which can be divided into the three regions described above: Si-rich, SiNx:H with an equal ratio of Si and N to each other, and N-rich. On the back side of the solar cell, a layer stack consisting of a boron emitter layer (p+emitter) 5, an aluminum oxide layer (Al₂O₃) 6 and a cover layer 7 of SiNx:H, which has the same properties as the cover layer 4 on the front side, is deposited on the c-Si(n) substrate layer 2. Metal contacts 8, for example of silver (Ag), are deposited on both the front and back sides in the regions where the cover layers 4 and 7 have been removed. This can be done with all methods known in the prior art.

By using C-rich μ c-SiCx with a C/Si ratio (x) of >0.7 with high binding energies of 432 KJ/mol of C—H bonds compared to 318 KJ/mol of Si—H bonds, high-temperature stable hydrogenated μ c-SiCx can be obtained. In addition, the high carbon content in the SiC network having a C/Si ratio (x) of >0.7 ensures a bubble-free thin layer.

Previous work [4] shows that adding carbon to the SiC network shifts the high-temperature effusion peak to higher temperatures, indicating better temperature stability of the hydrogen. The shift of the effusion peak, namely in the range of 500° C. to 650° C., is explained by a higher diffusion energy. This signifies a lower diffusion coefficient for atomic hydrogen due to the incorporation of carbon and thus a higher temperature stability of atomic hydrogen in the network. F-ISE [5] also reports that the use of C-rich a-SiC (without tunnel oxide) as a back-side passivation layer shows promising hydrogenation quality after an industrial firing step. However, μ c-SiCx is used here together with the tunnel oxide only as a passivated front-side contact.

The previously described SiNx:H cover layer with a concentration gradient can be used both as a cover layer and as an anti-reflective layer. Previous work [6] shows that N-rich SiNx shifts the hydrogen effusion peak from 550° C. to 800° C. A temperature of 800° C. was considered to be the controlling temperature, since the firing process during metallization is often carried out at such temperature. Layer stacks of SiNx with an N concentration gradient (Si-rich SiNx/SiN/N-rich SiNx) can further drastically reduce the overall hydrogen effusion. By using SiNx with a concentration gradient, hydrogen effusion can be prevented at high temperatures, due to the high binding energies of N—H bonds and compact density. Hydrogen effusing from the c-Si(n)/SiO₂ interface or the hydrogenated μ c-SiC at high temperatures starting at approximately 400° C. is retained in the cell and can diffuse back into the c-Si(n)/SiO₂ interface and contribute to hydrogenation. In the exemplary embodiment shown here in FIG. 1, boron-diffused emitters (p⁺ emitters) are used, which is a proven standard technology.

FIG. 2 differs from the embodiment according to FIG. 1 by the arrangement of a layer stack on the back side of the solar cell, comprising a silicon oxide layer SiOx 9, a poly-Si(p) layer 10 and the covering layer 7 of SiNx:H with the different Si and N concentration sections already described. The SiOx tunnel oxide/poly-Si(p) stack passivates the metal contacts, whereby recombination at the metal-semiconductor interface can advantageously be optimized.

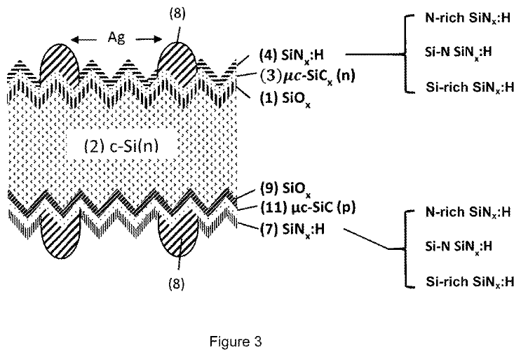

FIG. 3 differs from the embodiment according to FIG. 1 by the arrangement of a layer stack on the back side of the solar cell, comprising a silicon oxide layer SiOx 9, a p-type μ c-SiCx layer 11 and the covering layer 7 of SiNx:H already described. In order to reduce the parasitic absorption of the poly-Si otherwise used in the prior art, in such embodiment a p-type μ c-SiCx layer 11 was advantageously also used on the back side, enabling μ c-SiCx passivated contacts on both sides (see FIG. 3). Such design of a solar cell is advantageous for the method for production, because both SiNx and SiC may be deposited by means of HWCVD, simplifying the production process.

In the following, exemplary methods and the respective parameters set for depositing a tunnel oxide layer of silicon oxide, a silicon carbide layer and a silicon nitride layer are described:

1. Deposition of a tunnel oxide layer of SiO₂ with a layer thickness in the range of 1.5 nm

### a) Ozone Oxidation:

TABLE 1
Suitable process parameters for the deposition of
a tunnel oxide layer of SiO₂ by ozone oxidation

| HCl | O₃ | H₂O | pH | Temperature | Time |
|---|---|---|---|---|---|
| 1-10 ml | 5-30 ppm | 16000 ml | 1-5 | Room | 5-30 min |
| | | | | temperature- | |
| | | | | 50° C. | |

The ozone oxidation method is a method known to a person skilled in the art and is described, for example, in [8].

### b) Piranha Oxidation:

TABLE 2
Suitable method parameters for the deposition of
a tunnel oxide layer of SiO₂ by piranha oxidation

| H₂O₂:H₂SO₄ | Temperature | Time |
|---|---|---|
| 3:1-1:2 | 50-150° C. | 5-30 min |

The Piranha oxidation method is a method known to a person skilled in the art and is described, for example, in [9].

Both the tunnel oxide layer of AlOx and the tunnel oxide layer of SiOx may also be prepared by an ALD (atomic layer deposition) method. However, the precursors for this are different. For SiOx, the precursors are tris(dimethylamino) silane (TDMAS) and oxygen, while for AlOx, trimethylaluminum (Al(CH₃)₃, TMA) and deionized water (H₂O, DIW) are used. Such

methods are known to a person skilled in the art for ALD-AlOx for example from and for ALD-SiOx from [13],

2. Deposition of an SiC layer with a band gap in the range of 2.3-2.9 eV and an electrical dark conductivity in the range of 1E-12 to 0.9 S/cm

The optical and electrical properties of SiC layers are mainly affected by the filament temperature during deposition [10; 11].

### Method: Hot Wire Chemical Vapor Deposition (HWCVD)

TABLE 3
Process parameters for depositing
an SiC layer by means of HWCVD

| | | | | Sub- | Depo- | Layer |
|---|---|---|---|---|---|---|
| | | | Filament | strate | sition | thick- |
| H₃Si—CH₃ | N₂ | H₂ | T | spacing | time | ness |
| 2-16 | 0-100 | 10-500 | 1600-2200 | 40-100 | 5-50 | 10-400 |
| sccm | sccm | sccm | ° C. | mm | min | nm |

3. Deposition of SiNx layers with a band gap of 2.6-5.7 eV and a refractive index at 632 nm of 1.8-3:

### Dielectric Material

It is assumed that over a wide range of deposition conditions, the optical properties of SiNx layers depend on the ratio of [Si—H] to [N—H], rather than the ratio of [Si—N], [Si—H] and [N—H] [7].

### Method: Plasma Enhanced Chemical Vapor Deposition (PECVD)

TABLE 4
Process parameters for depositing SiNx cover layers by means
of PECVD, which have regions with different Si or N content:

| Composition | | | | Layer | | | | |
|---|---|---|---|---|---|---|---|---|
| of different | SiH₄ | N₂ | Ratio | thickness | Refractive | Temperature | Pressure | Energy |
| regions | [sccm] | [sccm] | N/Si | [nm] | index | [° C.] | [mbar] | [W] |
| Si-rich | 6 | 300 | 0.4 | 75 | 2.8 | 450 | 0.8 | 60 |
| S~N | 4.5 | 300 | 0.9 | 75 | 2.4 | 450 | 0.8 | 60 |
| N-rich | 1.5 | 300 | 1.1 | 75 | 2.1 | 450 | 0.8 | 60 |
| Triple layer | 6/4.5/1.5 | 300 | 0.4/0.9/1.1* | 25/20/30 | 2.8/2.4/2.1 | 450 | 0.8 | 60 |
| Si-rich + | | | | | | | | |
| Si~N + | | | | | | | | |
| n-rich | | | | | | | | |

*Triple layer with N/Si ratio with Si-rich of 0.4; Si~N of 0.9 and N-rich of 1.1.

While embodiments have been described and depicted in detail in the preceding part of the application, this description and the figures are intended merely to apply as an example without thereby acting in a limiting manner. Further embodiments with any type of combination of the features mentioned in the context of individual embodiments are included in the scope of the present disclosure.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LITERATURE

[1] Lai, Y., et al., In Situ Doping of Nitrogen in <110>-Oriented Bulk 3CSiC by Halide Laser Chemical Vapour Deposition. Materials (Basel, Switzerland), 2020. 13 (2): p. 410.
[2] Latha, H. K. E., A. Udayakumar, and V. Siddeswara Prasad, Effect of Nitrogen Doping on the Electrical Properties of 3C-SiC Thin Films for High-Temperature Sensors Applications. Acta Metallurgica Sinica (English Letters), 2014. 27 (1): pp. 168-174.
[3] Haschke, J., et al., Lateral transport in silicon solar cells. Journal of Applied Physics, 2020. 127 (11): p. 114501.
[4] Ehling, C., et al. Electronic surface passivation of crystalline silicon solar cells by a-SiC:H. in 2010 35th IEEE Photovoltaic Specialists Conference. 2010.
[5] Glunz, S. W., et al. Surface Passivation of Silicon Solar Cells using Amorphous Silicon Carbide Layers, in 2006 IEEE 4th World Conference on Photovoltaic Energy Conference. 2006.
[6] Jafari, S., et al., Composition limited hydrogen effusion rate of a-SiNx:H passivation stack. AIP Conference Proceedings, 2019. 2147 (1): p. 050004.
[7] Yimao Wan, Keith R. McIntosh, and Andrew F. Thomson, Characterisation and optimisation of PECVD SiNx as an antireflection coating and passivation layer for silicon solar cells, AIP Advances 3, 032113 (2013); https://doi.org/10.1063/1.47951083, 032113
[8] Kaifu Qiu et al., Development of Conductive SiCx:H as a New Hydrogenation Technique for Tunnel Oxide Passivating Contacts, ACS Applied Materials & Interfaces 2020 12 (26), 29986-29992; DOI: 10.1021/acsami.0c06637
[9] Malte Köhler et al., Wet-Chemical Preparation of Silicon Tunnel Oxides for Transparent Passivated Contacts in Crystalline Silicon Solar Cells, ACS Applied Materials & Interfaces 2018 10 (17), 14259-14263; DOI: 10.1021/acsami.8b02002
[10] M. Köhler et al., Development of a Transparent Passivated Contact as a Front Side Contact for Silicon Heterojunction Solar Cells, 2018 IEEE 7th World Conference on Photovoltaic Energy Conversion (WCPEC) (A Joint Conference of 45th IEEE PVSC, 28th PVSEC & 34th EU PVSEC), Waikoloa Village, HI, 2018, pp. 3468-3472, doi: 10.1109/PVSC.2018.8548008
[11] M. Köhler et al., Optimization of Transparent Passivating Contact for Crystalline Silicon Solar Cells, in IEEE Journal of Photovoltaics, vol. 10, no. 1, pp. 46-53, January 2020, doi: 10.1109/JPHOTOV.2019.2947131
[12] Hamchorom Cha, Hyo Sik Chang, Passivation performance improvement of ultrathin ALD-Al₂O₃film by chemical oxidation, H. Cha, H. S. Chang/Vacuum 149 (2018) 180-184
[13] Mickael Lozach, Shota Nunomura, Koji Matsubara, Double-sided TOPCon solar cells on textured wafer with ALD SiOx layer, Solar Energy Materials and Solar Cells 207 (2020) 110357

1. A layered structure for a solar cell having tunnel-oxide-passivated contacts, the layered structure comprising:
at least one tunnel oxide layer; and
a μc-SiCx layer, wherein x≥0.5.

2. The layered structure according to claim 1, wherein the μc-SiCx layer is a hydrogenated μc-SiCx:H(n) layer.

3. The layered structure according to claim 1, wherein the μc-SiCx layer has a layer thickness in a range of 30 to 200 nm.

4. The layered structure according to claim 1, wherein the μc-SiCx layer has a band gap of 2.3 to 2.9 eV.

5. The layered structure according to claim 1, wherein carbon is added to the μc-SiCx layer.

6. The layered structure according to claim 1, wherein carbon is added to the μc-SiCx layer, wherein the ratio of Si to C is in a range of 1.0 to ≥0.7 to 1.0.

7. The layered structure according to claim 1, wherein the tunnel oxide layer is a silicon oxide layer SiOx, with wherein x=1-2, or an aluminum oxide layer AlOx, wherein x=1-2.

8. The layered structure according to claim 1, wherein the tunnel oxide layer is a silicon oxide layer SiOx or aluminum oxide layer AlOx, the tunnel oxide layer having a layer thickness in a range of 1-2 nm.

9. The layered structure according to claim 1, wherein the tunnel oxide layer is:
a silicon oxide layer SiOx deposited by piranha oxidation, by thermal oxidation or by ozone oxidation, or
is an ALD-grown silicon oxide layer SiOx or aluminum oxide layer AlOx.

10. The layered structure according to claim 1, wherein the layered structure is arranged on a front side of the solar cell.

11. The layered structure according to claim 1, wherein the layered structure is transparent.

12. The layered structure according to claim 1, wherein the layered structure is arranged on a front side and on a back side of the solar cell.

13. The layered structure according to claim 1, further comprising at least one cover layer is deposited on the μc-SiCx layer.

14. The layered structure according to claim 1, further comprising at least one cover layer deposited on the μc-SiCx layer, the at least one cover layer comprising material that prevents hydrogen effusion.

15. The layered structure according to claim 1, comprising at least one cover layer is deposited on the μc-SiCx layer, the at least one cover layer comprising a SiNx:H layer with x=0.3 to 1.5.

16. The layered structure according to claim 15, wherein the cover layer of SiNx:H has a concentration gradient with respect to Si content and N content.

17. The layered structure according to claim 15, wherein the cover layer is divided into three concentration sections with respect to Si content and N content.

18. A solar cell having tunnel-oxide-passivated contacts, the solar cell comprising:
at least one crystalline n-doped or p-doped silicon layer, and
a layered structure according to claim 1 deposited as a front-side contact or as a front-side and back-side contact.

19. A method for producing a layered structure for a solar cell having tunnel-oxide-passivated contacts, the method comprising:
providing a substrate layer comprising a silicon layer;
depositing a tunnel oxide layer on the substrate layer; and
depositing a μ c-SiCx:H layer, which is n-doped or p-doped, on the tunnel oxide layer so as to provide a μc-SiCx layer, wherein x≥0.5.

20. The method according to claim 19, further comprising depositing a cover layer on the μ c-SiCx:H layer.

21. The method according to claim 20, further comprising depositing at least one cover layer, which consists of a material that prevents hydrogen effusion, on the μc-SiCx layer.
